(19) United States
(12) Patent Application Publication
(10) Pub. No.: US 2019/0198807 A1
(43) Pub. Date: Jun. 27, 2019

(54) BARRIER FILM AND BARRIER STRUCTURE INCLUDING THE SAME

(71) Applicant: Industrial Technology Research Institute, Hsinchu (TW)

(72) Inventors: Wen-Hung Liu, Taichung City (TW); Cheng-Yi Chen, Taichung City (TW); Hao-Che Kao, Taipei City (TW); Hsin-Chu Chen, Miaoli County (TW)

(73) Assignee: Industrial Technology Research Institute, Hsinchu (TW)

(21) Appl. No.: 16/231,959

(22) Filed: Dec. 25, 2018

Related U.S. Application Data
(60) Provisional application No. 62/610,266, filed on Dec. 25, 2017.

(51) Int. Cl. H01L 51/52; C08G 77/54; C09D 183/14; C09D 5/24; C08J 7/04; H01L 51/00

(52) U.S. Cl. CPC H01L 51/5253; C08G 77/54; C09D 183/14; H01L 51/56; C08J 7/042; H01L 51/0094; C09D 5/24

(57) ABSTRACT

Provided is a barrier film which includes an organo-silicon polymeric composition having Si₃—N₄ bonds and Si—OH bonds. The peak height of Si₄—N₄ bonds in an infrared absorption spectrum is represented by A, and the peak height of Si—OH bonds in the infrared absorption spectrum is represented by B; and a ratio of A to B is greater than 2.

### CROSS-REFERENCE TO RELATED APPLICATION

This application claims the priority benefit of U.S. provisional application Ser. No. 62/610,266, filed on Dec. 25, 2017. The entirety of the above-mentioned patent application is hereby incorporated by reference herein and made a part of this specification.

### TECHNICAL FIELD

The disclosure relates to a barrier film and a barrier structure including the same.

### BACKGROUND

Organic light-emitting devices (OLEDs) have been used in various mobile devices because of their advantages over conventional light sources such as large illumination area, low power consumption, lightweight, slimness and flexibility, etc. Nevertheless, OLEDs are liable to be deteriorated due to invasion of moisture and oxygen, which may reduce their operational performance and lifetime. Various barrier films with low WVTR/OTR and improved optical characteristics are proposed to overcome those issues.

### SUMMARY

An embodiment of the disclosure provides a barrier film including an organo-silicon polymeric composition having Si₄—N₄ bonds and Si—OH bonds. A peak height of Si₄—N₄ bonds in an infrared absorption spectrum is represented by A, and the peak height of Si—OH bonds in the infrared absorption spectrum is represented by B; and a ratio of A to B is greater than 2.

An embodiment of the disclosure provides a barrier structure including a substrate; and a first barrier film disposed over the substrate, the first barrier film comprising a first organo-silicon polymeric composition having Si₃—N₄ bonds and Si—OH bonds, wherein a peak height of Si₄—N₄ bonds in an infrared absorption spectrum is represented by A1, a peak height of Si—OH bonds in the infrared absorption spectrum is represented by B1, and a ratio of A1 to B1 is greater than 2.

An embodiment of the disclosure provides a method for forming a barrier film. The method comprises forming an organo-silicon polymeric composition having Si₄—N₄ bonds and Si—OH bonds over a substrate, wherein a peak height of Si₄—N₄ bonds in an infrared absorption spectrum is represented by A, and a peak height of Si—OH bonds in the infrared absorption spectrum is represented by B; and a ratio of A to B is greater than 2.

In order to make the aforementioned and other features and advantages of the disclosure comprehensible, several exemplary embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 to FIG. 7 are schematic diagrams illustrating a method for manufacturing an OLED according to an embodiment of the disclosure.

FIG. 8A to FIG. 8B are cross-sectional views of barrier structures according to some embodiments of the disclosure.

FIG. 9A to FIG. 9C are schematic diagrams illustrating a method for manufacturing the barrier structure according to an embodiment of the disclosure.

FIG. 10A to FIG. 10E are cross-sectional views of different interior arrangements of barrier films in the barrier structure according to some embodiments of the disclosure.

FIG. 11 is a schematic diagram of the reaction mechanisms for the film deposition according to some embodiments of the disclosure.

### DESCRIPTION OF EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

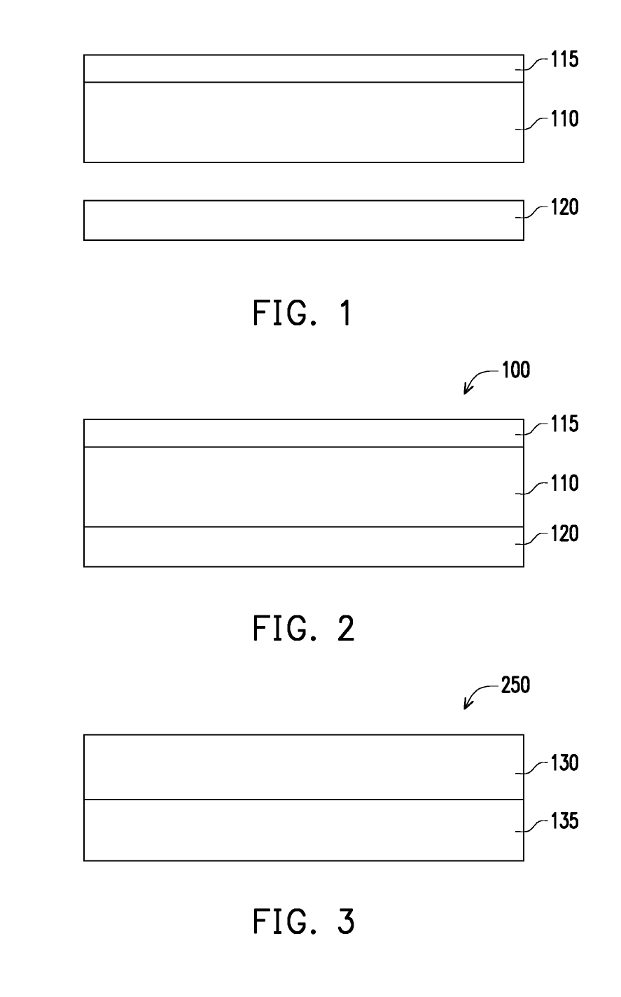

FIG. 1 to FIG. 7 are cross-sectional views illustrating a method for manufacturing an OLED according to an embodiment of the disclosure. The method for manufacturing an OLED will be described in more detail hereinafter.

Referring to FIG. 1, a sealing adhesive 110 is provided. The sealing adhesive 110 may be any commercially available sealing tapes which provide acceptable sealing capability and adhesion capability. The sealing adhesive 110 may be provided with a release film 115 covering thereon. In some embodiments, the release film 115 is disposed on one surface of the sealing adhesive 110. For example, the thickness of the sealing adhesive 110 ranges from about 30 μm to about 70 μm. As shown in FIG. 1, an optical reflective film 120 is provided. In some embodiments, the optical reflective film 120 includes a metal foil, such as aluminium foil, copper foil or the like. For example, the thickness of the optical reflective film 120 ranges from about 20 μm to about 40 μm.

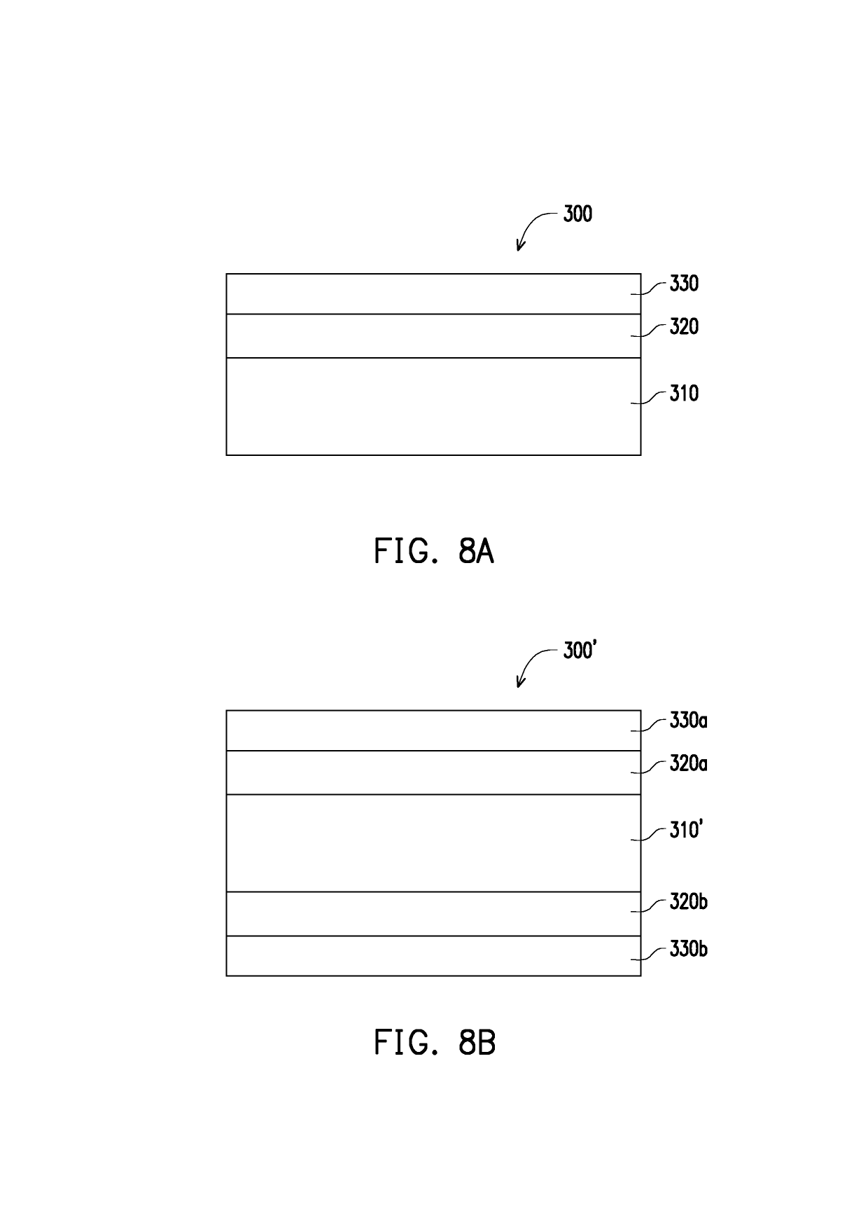

Referring to FIG. 2, a lamination process is performed to adhere the optical reflective film 120 with the other surface of the sealing adhesive 110 such that the optical reflective film 120 and release film 115 are adhered with opposite surfaces of the sealing adhesive 110 respectively. Here, the optical reflective film 120 may be any optical film capable reflecting and protecting an OLED illustrated in FIG. 7. Thus, a sealing member 100 including the sealing adhesive 110, the release film 115 and the optical reflective film 120 is accomplished.

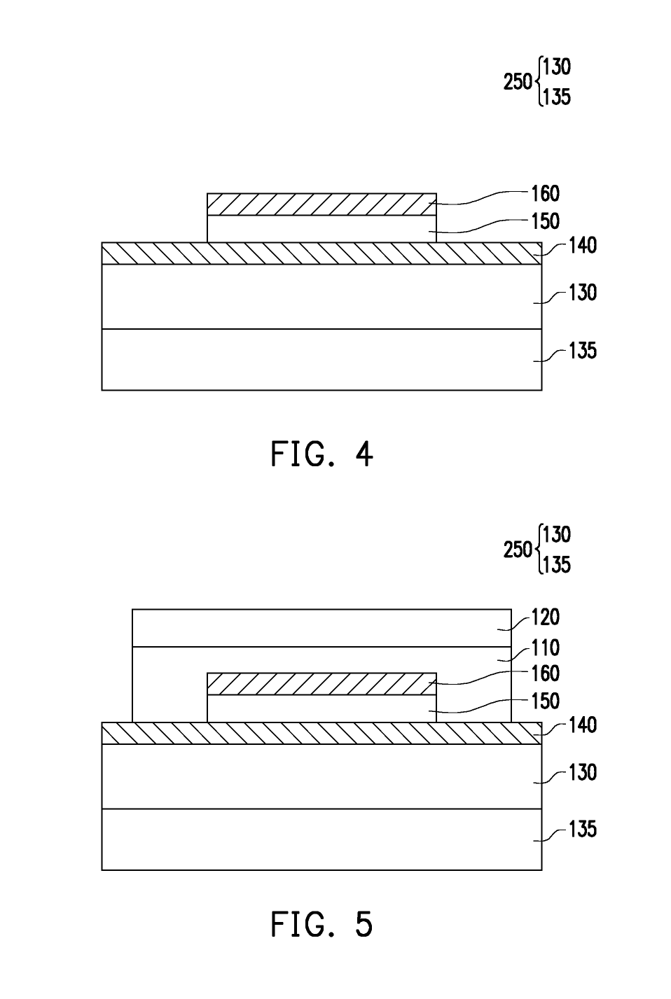

Next, referring to FIG. 3 and FIG. 4, a barrier member 250 including a barrier film 130 and a carrier 135 is provided. The barrier member 250 plays a role as a supporting base for the subsequent OLED fabrication. The description regarding the fabrication of the barrier member 250 will be discussed later and is omitted here. Then, an OLED including an anode layer 140, an organic light-emitting layer 150 and a cathode layer 160 is formed over a surface of the barrier member 250. For example, the OLED is an active matrix OLED or a passive matrix OLED. The active matrix or passive matrix OLED may serve as a display with display pixels or a light source without pixel design. In some embodiments, the anode layer 140, the organic light-emitting layer 150 and the cathode layer 160 may be formed by vacuum evaporation processes in the stated order over the barrier member 250, namely over the barrier film 130. For example, the anode layer 140 is a transparent conductive oxide layer (e.g., indium tin oxide layer, indium zinc oxide layer or the like) and the cathode layer 160 is a metal layer. The organic light-emitting layer 150 may include at least one organic layer capable of emitting light with predetermined wavelength. Furthermore, the OLED may further include at least one of the functional layers to enhance the performance thereof. For example, the OLED may further include an electron injection layer (EIL) and/or an electron transport layer (ETL) disposed between the organic light-emitting layer 150 and the anode layer 140. Furthermore, the OLED may further include a hole injection layer (HIL) and/or a hole transport layer (HTL) disposed between the organic light-emitting layer 150 and the cathode layer 160.

Referring to FIG. 2 and FIG. 5, the release film 115 is removed from the sealing adhesive 110 prior to an encapsulation process for the OLED. The encapsulation process for the OLED is then performed by laminating the sealing adhesive 110 having the optical reflective film 120 formed thereon onto the barrier member 250 to entirely encapsulate the OLED including the anode layer 140, the organic light-emitting layer 150, and the cathode layer 160. Here, the sealing member 100 including the sealing adhesive 110 and the optical reflective film 120 is pressed onto the OLED and the barrier member 250 such that the sealing adhesive 110 deforms to some extents so as to better fit the topography the OLED including the anode layer 140, the organic light-emitting layer 150, and the cathode layer 160. After lamination of the barrier member 250, other processes such as curing and edge encapsulation processes to further enhance the resistance against outer environmental issues may be conducted.

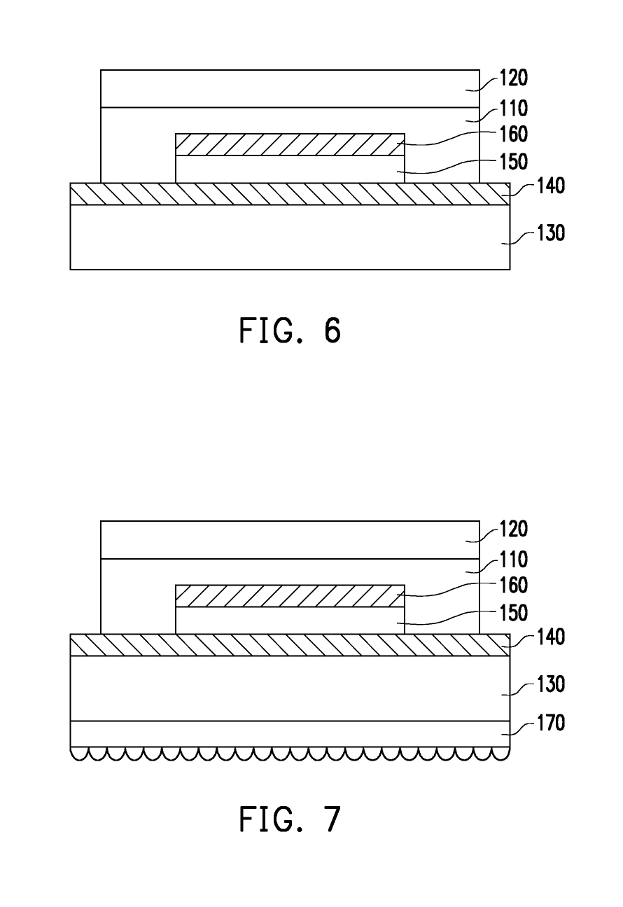

Referring to FIG. 6, the carrier 135 is detached from the barrier film 130. An out-coupling film (OC film) 170 may be attached onto the bottom surface which was originally covered by carrier 135 to improve optical properties of the finished OLED. Hence, an OLED package with low WVTR/OTR is provided.

OLEDs are liable to be deteriorated due to invasion of moisture and oxygen, which may substantially reduce their operational performance and lifetime. Various barrier films with low WVTR/OTR and improved optical characteristics are proposed in this disclosure. Further, there are also demands for barrier films which may reduce surface roughness caused by processing defects (e.g., pinholes and particles).

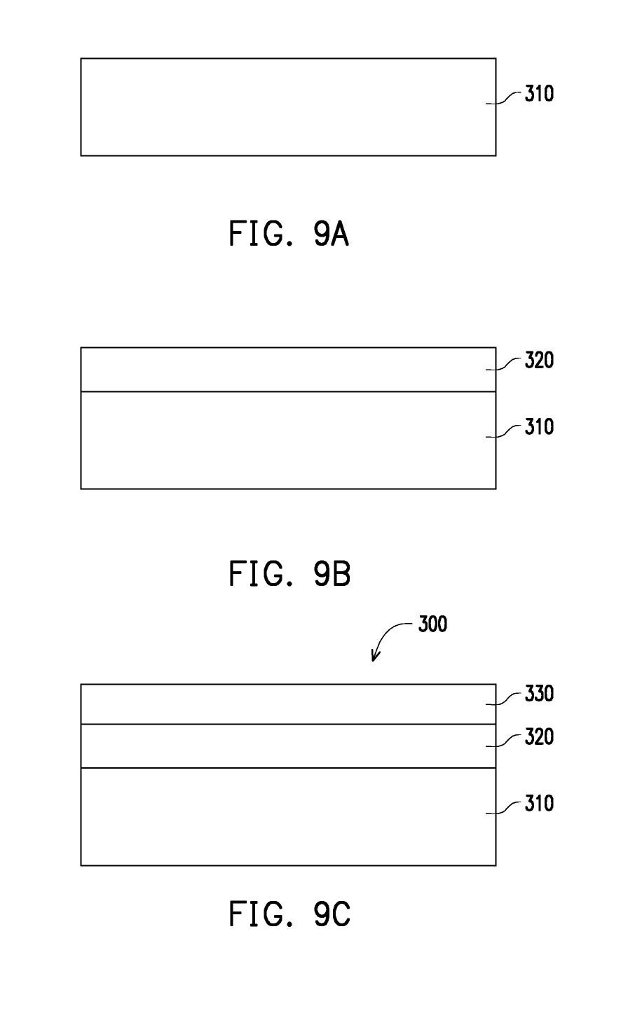

In an embodiment of the disclosure, a barrier structure 300 with low WVTR/OTR and improved optical characteristics such as high light-transmittance, high refractive index etc. is shown in FIG. 8A. Referring to FIG. 8A, the barrier structure 300 includes a substrate 310 and a barrier film 330 disposed over the substrate 310. The barrier film 330 includes an organo-silicon polymeric composition having Si₃—N₄ bonds and Si—OH bonds. The method for manufacturing the barrier structure 300 as shown in FIG. 9A to FIG. 9C will be described in more detail hereinafter.

Referring to FIG. 9A, the substrate 310 is provided. The material of the substrate 310 may be any materials having Tg less than 150° C., for example, plastics such as polyethylene naphthalate, polyethylene terephthalate, cylco-olefin polymer or the like. In some embodiments, the substrate 130 is a flexible substrate. In some alternative embodiments, the substrate 130 is a rigid substrate. Next, a cleaning process may be then performed on the substrate 310.

Referring to FIG. 9B, a wet coating process is performed on the substrate 310 to form a planarization layer 320 over the substrate 310. The wet coating process may be selected from spray coating, spin coating, ink-jet printing or the like. The materials for forming the planarization layer 320 may include metal oxide, silicon oxide-based material containing metal oxide particles, poly(methyl methacrylate) (PMMA) containing metal oxide particles or the like. In an embodiment of the disclosure, the metal oxide particles in the planarization layer 320 may be ZrO₂, TiO₂ or the like. In an embodiment of the disclosure, the particle scale of the metal oxide ranges from 0.3 μm to 1 μm. Through the wet coating process, the planarization layer 320 may cover or fill the surface defects (e.g., pinholes and particles) on the surface of the substrate 310 such that the roughness of the surface of the substrate 310 is reduced. In an embodiment of the disclosure, the thickness of the planarization layer may range between 1 μm and 2 μm. In another embodiment of the disclosure, the planarization layer 320 may exhibit a WVTR (water vapor transmission rate) about 0.1 g/m² day ˜10 g/m² day. In still another embodiment of the disclosure, the roughness of the planarization layer 320 is measured to be Ra<1 nm and Rz<15 nm.

Next, referring to FIG. 9C, a barrier film 330 is formed on the planarization layer 320 by a CVD process, for example. In an embodiment of the disclosure, the barrier film 330 is formed by a ICP-PECVD process which may be conducted under low process temperature. In an embodiment of the disclosure, the barrier film 330 may include an organo-silicon polymeric composition having Si₃—N₄ bonds and Si—OH bonds. In the embodiment of the disclosure, a peak height of Si₄—N₄ bonds in an infrared absorption spectrum is represented by A, a peak height of Si—OH bonds in the infrared absorption spectrum is represented by B, and a ratio of A to B is greater than 2. In some embodiments, the ratio of B to A ranges between 0.4 and 0.5. It is believed that Si—OH bonds tend to cause swelling and plumping of the films, therefore the smoothness and flatness of the films could be deteriorated. Moreover, pinholes may arise in such films during the following elevated-temperature processes due to compression stress. Within the range (i.e. the ratio of A to B is greater than 2), less pinholes will occur during subsequent elevated-temperature processes of the barrier film according to the present disclosure.

In an embodiment of the disclosure, a first barrier film 330a may be disposed over one side of the substrate 310′, and a second barrier film 330b may be disposed over the other side of the substrate 310′ as shown in the barrier structure 300′ of FIG. 8B. The first barrier film 330a may include a first organo-silicon polymeric composition having Si₄—N₄ bonds and Si—OH bonds, wherein a peak height of Si₄—N₄ bonds in an infrared absorption spectrum is represented by A1, a peak height of Si—OH bonds in the infrared absorption spectrum is represented by B1, and a ratio of A1 to B1 is greater than 2. Further, the second barrier film 330b may include a second organo-silicon polymeric composition having Si₄—N₄ bonds and Si—OH bonds, wherein a peak height of Si₄—N₄ bonds in the infrared absorption spectrum is represented by A2, a peak height of Si—OH bonds in the infrared absorption spectrum is represented by B2, and a ratio of A2 to B2 is greater than 2. Within these ranges (i.e. the ratio of A1/B1 or A2/B2 is greater than 2), less pinholes will occur during subsequent elevated-temperature processes of the barrier films according to the present disclosure. In another embodiment of the disclosure, the first organo-silicon polymeric composition is the same as the second organo-silicon polymeric composition. In still another embodiment of the disclosure, the first organo-silicon polymeric composition is different from the second organo-silicon polymeric composition.

Referring to FIG. 9C again, the barrier structure 300 is thus provided. In an embodiment of the disclosure, the barrier structure 300 may have a planarization layer 320 sandwiched between a substrate 310 and a barrier film 330. In another embodiment of the disclosure, a planarization layer 320 may be optionally omitted.

The barrier film according to the disclosure and the fabrication thereof will be elucidated in more detail hereinafter by way of Examples.

The barrier film according to the present disclosure is thus provided. In an embodiment of the disclosure, there is provided a barrier film which includes an organo-silicon polymeric composition having Si₃—N₄ bonds and Si—OH bonds. The peak height of Si₄—N₄ bonds in an infrared absorption spectrum is represented by A, the peak height of Si—OH bonds in the infrared absorption spectrum is represented by B, and a ratio of A to B is greater than 2. In another embodiment of the disclosure, the ratio of B1 to A1 ranges between 0.4 and 0.5. Within the range, less pinholes will occur during subsequent elevated-temperature processes of the barrier film according to the present disclosure. In still another embodiment of the disclosure, the barrier film exhibits a WVTR (water vapor transmission rate) smaller than 5×10⁻⁵ g/m² day. In a further embodiment of the disclosure, a thickness of the barrier film ranges between about 50 μm and about 110 μm. Thus, barrier films according to the present disclosure with low WVTR/OTR and improved operational properties are obtained.

Besides having low WVTR/OTR to prevent deterioration of the devices, the barrier films used in OLEDs are expected to optimize the optical characteristics of the devices such as light-transmittance, refractive index and the like. Hence, barrier films according to the disclosure meeting at least these requirements are proposed.

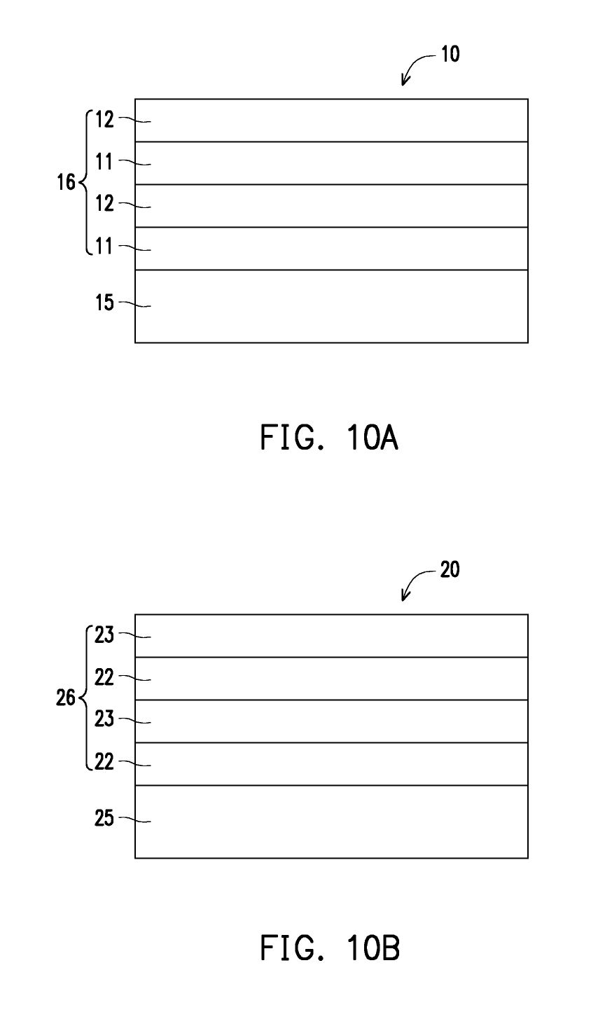

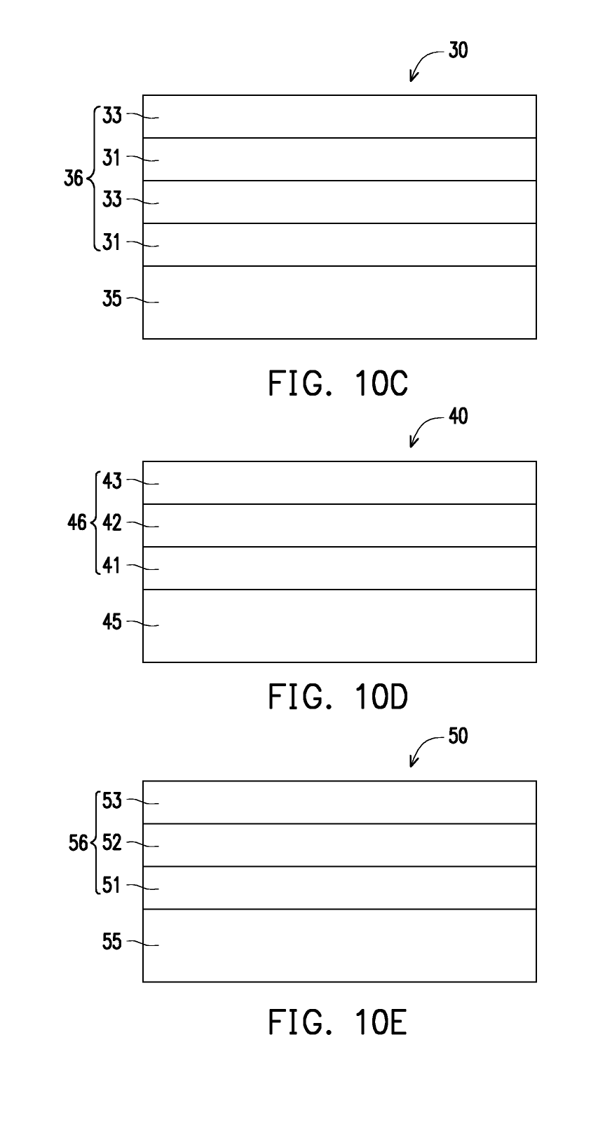

Referring to FIG. 10A to FIG. 10E, barrier structures 10, 20, 30, 40, and 50 with barrier films 16, 26, 36, 46, and 56 having multiple stacked barrier regions 11, 12, 22, 23, 31, 33, 41, 42, 43, 51, 52, and 53 are shown. The substrates 15, 25, 35, 45, and 55 of the barrier structures 10, 20, 30, 40, and 50 are similar to the substrate 310 of the barrier structure 300 of FIG. 8A and the description thereof will be omitted here. In some embodiments of the disclosure, the ratio of the main elements such as carbon, silicon, and oxygen in the organo-silicon polymeric composition may be adjusted depending on the in-situ recipes for chemical vapour deposition (CVD). A plurality of stacked barrier regions with different element ratios are thus formed on the substrate. It should be noted that the amounts of elements are denoted by weight percentage in the specification. For example, in an embodiment of the present disclosure, the element ratio of the organo-silicon polymeric composition in first barrier regions 11, 31, 41, and 51 may be C>Si>O. The element ratio of the organo-silicon polymeric composition in second barrier regions 12, 22, 42, and 52 may be C>Si>O. The element ratio of the organo-silicon polymeric composition in third barrier regions 23, 33, 43, and 53 may be Si>O>C. It should be noted that the refractive index of each of the plurality of stacked barrier regions varies depending on its composition. In some embodiments of the disclosure, the refractive index of each of the barrier region may be the same or may be different. Further, in the barrier films 16, 26, 36, 46, and 56, the plurality of stacked barrier regions are arranged in certain order. Specifically, referring to FIG. 10A to FIG. 10C, the plurality of stacked barrier regions are disposed in the sinusoidal arrangement, and referring to FIG. 10D and FIG. 10E, the plurality of stacked barrier regions are disposed in the monotonic arrangement. That is to say, referring to FIG. 10A to FIG. 10C, in some embodiments of the disclosure, the distribution of the refractive indices of the barrier films 16, 26, 36 composed of the plurality of stacked barrier regions 11, 12, 22, 23, 31, and 33 may vary periodically. In other embodiments of the disclosure, referring to FIG. 10D and FIG. 10E, the distribution of the refractive indices of the barrier films 46 and 56 composed of the plurality of stacked barrier regions 11, 12, 22, 23, 31, and 33 may not vary periodically. In further embodiments of the disclosure, the thickness of each of the barrier region may be the same or may be different. It should be noted that although the stacked barrier regions illustrated in the figures are distinctly distinguished from each other, the actual boundaries may be indefinite due to the inherent nature of the (CVD) process.

Hereinafter, the present disclosure is illustrated through Example 1 and Example 2 regarding fabrication of the barrier films. However, the disclosure is not restricted thereto.

Reaction Mechanisms of the Film Deposition

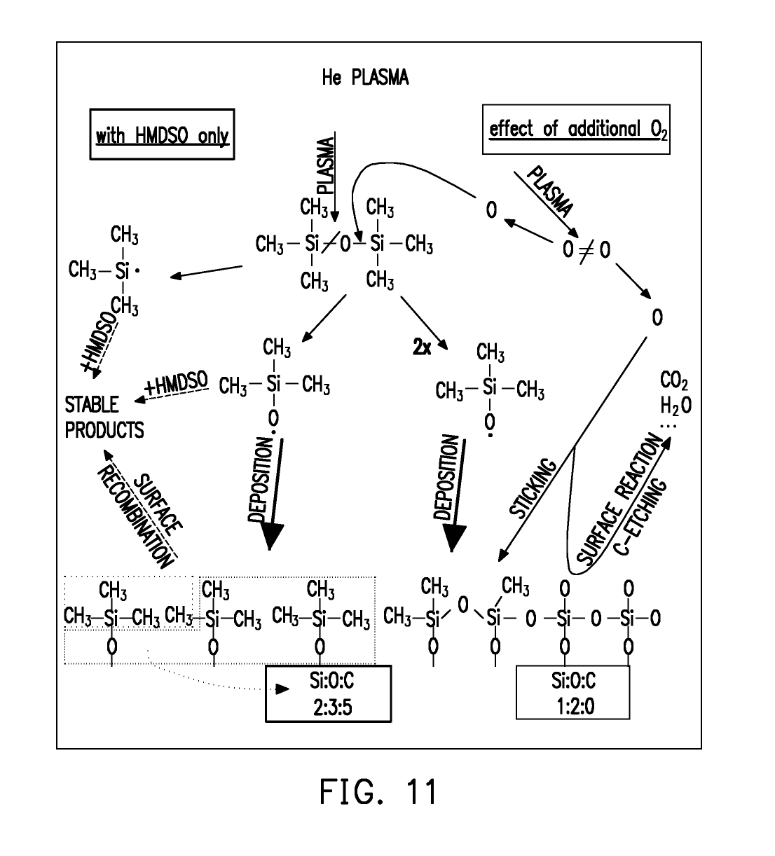

FIG. 11 is a schematic diagram of the reaction mechanisms for the film deposition according to some embodiments of the disclosure. The barrier films according to the disclosure are formed by CVD process as describe above. Here are some chemical equations which are believed to take place during the CVD process while using hexamethyldisiloxane (HMDSO) as the main precursor:

C₁₆H₁₈SiO₂+3N₂O→2SiO₂(CH₃)₃+3N₂ [Equation 1]

C₁₆H₁₈SiO₂+24N₂O→2SiO₂+6CO₂+9H₂O+24N₂ [Equation 2]

The dominance of Equation 1 or Equation 2 depends on the respective conditions and recipes while depositing these films. Specifically, if the amounts of O₂ is much more than the amounts of HMDSO in the recipes, it is observed that the reaction of Equation 2 will dominant. Or else the reaction of Equation 1 will take place dominantly during the deposition. Further, referring to FIG. 11, the elemental ratios of silicon, oxygen, and carbon of resulting deposited films are about 2:3:5 for Equation 1 and about 1:2:0 for Equation 2.

### EXAMPLE 1

A barrier film in sinusoidal arrangement, such as the arrangement shown in FIG. 10A, is fabricated using the conditions and recipes shown in Table 1. The barrier film of this example is composed of two stacked barrier regions with different elemental ratios. These stacked barrier regions are deposited sequentially by the inductively coupled plasma—plasma-enhanced CVD (ICP-PECVD) with altering the conditions and recipes in-situ. The barrier film according to the disclosure is thus obtained and the properties thereof are shown in Table 2. Moreover, the elemental ratios are C>Si>O in the barrier region I, and C≥Si>O in the barrier region II, respectively.

TABLE 1

| | | HMDSO | N₂O | Pressure | Power | Time |
|---|---|---|---|---|---|---|
| | Temperature | (sccm) | (sccm) | (mtorr) | (W) | (sec) |
| barrier | <80° C. | 100~500 | 10~100 | 50~100 | 500~1000 | 100~300 |
| region I | | | | | | |
| barrier | <80° C. | 20~100 | 100~1000 | 20~50 | 1000~3000 | 300~500 |
| region II | | | | | | |

TABLE 2

| | | Thickness | |
|---|---|---|---|
| | Elemental ratio | (nm) | WVTR (g/m2 day) |
| barrier region I | 60%:20%:10% | 300~500 | 0.1~10 |
| barrier region II | 40%:40%:20% | 100~300 | 1~10⁻¹ |

### EXAMPLE 2

A barrier film in monotonic arrangement, such as the arrangement shown in FIG. 10D or FIG. 10E, is fabricated using the conditions and recipes shown in Table 3. The barrier film of this example is composed of three stacked barrier regions with different elemental ratios. These stacked barrier regions are deposited sequentially by the ICP-PECVD with altering the conditions and recipes in-situ. The barrier film according to the disclosure is thus obtained and the properties thereof are shown in Table 4. Moreover, the elemental ratios are C>Si>O in the barrier region I, C≥Si>O in the barrier region II, and Si≥O>C in the barrier region III respectively.

TABLE 3

| | | HMDSO | N₂O | Pressure | Power | Time |
|---|---|---|---|---|---|---|
| | Temperature | (sccm) | (sccm) | (mtorr) | (W) | (sec) |
| barrier | <80° C. | 100~500 | 0~50 | 20~50 | 500~1000 | 60~300 |
| region I′ | | | | | | |
| barrier | <80° C. | 100~500 | 10~100 | 50~100 | 500~1000 | 120~300 |
| region II′ | | | | | | |
| barrier | <80° C. | 20~100 | 100~1000 | 20~50 | 1000~3000 | 300~500 |
| region III′ | | | | | | |

TABLE 4

| | | Thickness | |
|---|---|---|---|
| | Elemental ratio | (nm) | WVTR (g/m² day) |
| barrier region I′ | 60%:20%:10% | 300~500 | 0.1~10 |
| barrier region II′ | 40%:40%:20% | 100~300 | 1~10⁻¹ |
| barrier region III′ | 50%:40%:10% | 50~200 | 10⁻¹~10⁻³ |

The barrier film and the barrier structure comprising the same according to the present disclosure are explained correspondingly hereinbefore. In summary, the barrier film according to the present disclosure has the advantages over conventional barrier films such as low WVTR/OTR and improved optical characteristics such as high light-transmittance, high refractive index and etc. Further, less pinholes will occur during subsequent elevated-temperature processes of the barrier film according to the present disclosure. In addition, by providing a planarization layer in the barrier structure according to the present disclosure, surface defects (e.g., pinholes and particles) may be reduced and the surface roughness may be thus improved.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A barrier film, comprising:
an organo-silicon polymeric composition having Si₃—N₄ bonds and Si—OH bonds,
wherein a peak height of Si₄—N₄ bonds in an infrared absorption spectrum is represented by A, and a peak height of Si—OH bonds in the infrared absorption spectrum is represented by B; and
a ratio of A to B is greater than 2.

2. The barrier film of claim 1, wherein the ratio of B to A ranges between 0.4 and 0.5.

3. The barrier film of claim 1, wherein the barrier film exhibits a water vapor transmission rate smaller than 5×10⁻⁵ g/m² day.

4. The barrier film of claim 1, wherein a thickness of the barrier film ranges between 50 μm and 110 μm.

5. The barrier film of claim 1, further comprising a plurality of stacked barrier regions.

6. The barrier film of claim 5, wherein the plurality of stacked barrier regions comprises a plurality of first barrier regions and a plurality of second barrier regions stacked alternately;
a first refractive index of the plurality of first barrier regions is different from a second refractive index of the plurality of second barrier regions.

7. The barrier film of claim 6, wherein the plurality of stacked barrier regions comprise silicon, carbon, and oxygen as main elements, and the relative quantities of the main elements in the stacked barrier regions are expressed as elemental ratios; and
a first elemental ratio of the first barrier region and a second elemental ratio of the second barrier region are different from each other.

8. The barrier film of claim 7, wherein the first elemental ratio of the first barrier region is C>Si>O, and the second elemental ratio of the second barrier region is C≥Si>O.

9. The barrier film of claim 5, wherein the plurality of stacked barrier regions comprises a first barrier region, a second barrier region, and a third barrier region stacked alternately; and
a first refractive index of the first barrier region, a second refractive index of the second barrier region and a third refractive index of the third barrier region are different from one another.

10. The barrier film of claim 9, wherein the plurality of stacked barrier regions comprise silicon, carbon, and oxygen as main elements, and the relative quantities of the main elements in the stacked barrier regions are expressed as elemental ratios; and
a first elemental ratio of the first barrier region, a second elemental ratio of the second barrier region and a third elemental ratio of the third barrier region are different from one another.

11. The barrier film of claim 10, wherein the first elemental ratio of the first barrier region is C>Si>O, the second elemental ratio of the second barrier region is C≥Si>O, and the third elemental ratio of the third barrier region is Si≥O>C.

12. A barrier structure, comprising:
a substrate,
a first barrier film disposed over the substrate, the first barrier film comprising a first organo-silicon polymeric composition having Si₄—N₄ bonds and Si—OH bonds, wherein a peak height of Si₄—N₄ bonds in an infrared absorption spectrum is represented by A1, a peak height of Si—OH bonds in the infrared absorption spectrum is represented by B1, and a ratio of A1 to B1 is greater than 2.

13. The barrier structure of claim 12, further comprising:
a second barrier film disposed over the substrate, wherein the first barrier film and the second barrier film are disposed over opposite surfaces of the substrate.

14. The barrier structure of claim 13, wherein the second barrier film comprising a second organo-silicon polymeric composition having Si₃—N₄ bonds and Si—OH bonds, wherein a peak height of Si₄—N₄ bonds in the infrared absorption spectrum is represented by A2, a peak height of Si—OH bonds in the infrared absorption spectrum is represented by B2, and a ratio of A2 to B2 is greater than 2.

15. The barrier structure of claim 14, wherein the first organo-silicon polymeric composition is the same as the second organo-silicon polymeric composition.

16. The barrier structure of claim 14, wherein the first organo-silicon polymeric composition is different from the second organo-silicon polymeric composition.

17. The barrier structure of claim 12, wherein a material of the substrate comprises polyethylene naphthalate, polyethylene terephthalate, cylco-olefin polymer, or a combination thereof.

18. The barrier structure of claim 12, further comprising a planarization layer between the substrate and the first barrier film.

19. The barrier structure of claim 18, wherein a thickness of the planarization layer ranges between 1 μm and 2 μm.

20. A method for forming a barrier film, comprising:
forming an organo-silicon polymeric composition having Si₄—N₄ bonds and Si—OH bonds over a substrate,
wherein a peak height of Si₄—N₄ bonds in an infrared absorption spectrum is represented by A, and a peak height of Si—OH bonds in the infrared absorption spectrum is represented by B; and
a ratio of A to B is greater than 2.
